(19) United States
(12) Patent Application Publication
(10) Pub. No.: US 2007/0200564 A1
(43) Pub. Date: Aug. 30, 2007

(54) Magnetic Field Sensor, Sensor Comprising Same and Method for Manufacturing Same

(76) Inventors: Mario Motz, Wernberg (AT); Wolfgang Granig, Sachsenburg (AT); Christian Kolle, Villach (AT); Tobias Werth, Villach (AT)

Correspondence Address: BAKER BOTTS, L.L.P., 98 SAN JACINTO BLVD., SUITE 1500, AUSTIN, TX, 78701-4039, US

(21) Appl. No.: 11/421,673

(22) Filed: Jun. 1, 2006

(30) Foreign Application Priority Data
Feb. 28, 2006 (DE) 102006009238.4
May 12, 2006 (DE) 102006022336.5

(51) Int. Cl. G01R 33/02

(52) U.S. Cl. 324/247; 324/251; 324/252

(57) ABSTRACT

A magnetic field sensor has a first sensor with an output for a first signal indicating a magnetic field acting in a plane, and a second sensor having an output for a second signal indicating a component of the magnetic field perpendicular to the plane. The first sensor and the second sensor are applied on a common substrate by means of planar process steps.

### CROSS-REFERENCE TO RELATED APPLICATIONS

This application claims priority from German Patent Application No. 102006009238.4, which was filed on Feb. 28, 2006, and German Patent Application No. 102006022336.5, which was filed on May 12, 2006, which are incorporated herein by reference in their entirety.

### TECHNICAL FIELD

This invention relates to a magnetic field sensor and in particular to an error-compensated xMR sensor and to a sensor using such a magnetic field sensor, to methods for detecting and evaluating signals from such a magnetic field sensor and to a method for manufacturing the magnetic field sensor or the sensor, respectively.

### BACKGROUND

Sensors converting magnetic or magnetically encoded information into an electric signal play an ever greater role in current technology. They find application in all fields of technology in which the magnetic field may serve as an information carrier, i.e. for example in vehicle technology, in mechanical engineering/robotics, medical technology, non-destructive materials testing and in Microsystems technology. With the help of such sensors, a plurality of different mechanical parameters are detected, like e.g. position, speed, angular position, rotation speed, acceleration, etc., but also current flow, wear and tear or corrosion may be measured.

For detecting and evaluating magnetic or magnetically encoded information, in technology more and more magnetoresistive devices or sensor elements, respectively, are used. Magnetoresistive devices which may be arranged as individual elements or also in the form of a plurality of interleaved individual elements, are more and more used nowadays in numerous applications for contactless position and/or movement detection of a giver or sensor object with regard to a sensor arrangement in particular in automobile technology, like e.g. for ABS systems, systems for traction control, etc. For this purpose, frequently rotational angle sensors on the basis of magnetoresistive elements or structures, respectively, are used, which in xMR structures generally designate magnetoresistive structures, like e.g. AMR structures (AMR=anisotropic magnetoresistance), GMR structures (GMR=giant magnetoresistance), CMR structures (CMR=colossal magnetoresistance), TMR structures (TMR=tunnel magnetoresistance) or EMR structures (EMR=extraordinary magnetoresistance). In technical applications of GMR sensor applications, today preferably so-called spin valve structures are used, as they are, for example, illustrated in FIGS. 1a-c.

### SUMMARY

A magnetic field sensor may comprise a first sensor arranged to detect a magnetic field acting in a plane; and a second sensor arranged with regard to the first sensor in order to detect a component of the magnetic field perpendicular to the plane.

A method for detecting a magnetic field in a plane may comprise the following steps:
detecting an output signal of a first sensor detecting the magnetic field acting in the place;
detecting an output signal of a second sensor detecting a magnetic field component perpendicular to the plane; and
based on the output signal of the second sensor, correcting the output signal of the first sensor depending on the output signal of the second sensor.

A method for manufacturing a magnetic field sensor may comprise the following steps:
providing a substrate;
generating a first sensor structure on the substrate such that the sensor structure detects a magnetic field component applied perpendicular to a surface of the substrate; and
generating a second sensor structure on the substrate, wherein the second sensor structure is operative to detect a magnetic field in parallel to the surface of the substrate.

An improved magnetic field sensor and a method for manufacturing the same and a method for detecting a magnetic field avoid a corruption of measurement signals in the detection of a magnetic field in a detection plane.

### BRIEF DESCRIPTION OF THE DRAWINGS

In the following, with reference to the accompanying drawings, embodiments of the present invention are explained in more detail, in which:

FIG. 1(a)-(c) show schematical illustrations of the basic setup of different types of conventional GMR sensor elements and the associated schematical illustration of the magnetic field dependency of magnetization and resistance value of the magnetoresistive structure;

FIG. 2 shows a schematical illustration of a magnetoresistive TMR sensor element;

FIG. 3 shows an illustration of the change of the offset and the sensitivity of a GMR sensor depending on a magnetic field also acting perpendicular to the detection plane;

FIG. 4 shows a schematical illustration of a magnetic field sensor according to one embodiment;

FIG. 5(a) shows a GMR bridge having associated Hall sensors for a transverse sensitivity compensation;

FIG. 5(b) shows the arrangement of the four GMR sensors of FIG. 5(a) together with two Hall sensors on a common substrate;

FIG. 6(a) shows a schematical illustration of a magnetic field sensor according to a further embodiment with an optimum alignment of magnetic field and magnetic field sensor;

FIG. 6(b) schematically shows the distribution of the magnetic field components detected by the individual sensors in FIG. 6(a);

FIG. 7(a) shows the magnetic field sensor of FIG. 6(a) having an inclined alignment of magnetic field and magnetic field sensor;

FIG. 7(b) schematically shows the distribution of the magnetic field components detected by the individual sensors in FIG. 7(a);

FIG. 8 shows a top view illustration of a magnetic field sensor according to the further embodiment in a further implementation;

FIG. 9A shows a schematical illustration of a part of a magnetic field sensor according to a further embodiment having an additional magnetic field concentrator;

FIG. 9B shows a schematical illustration of a magnetic field sensor according to the embodiment of FIG. 9A in which the magnetic field concentrator is formed by the GMR sensor;

FIG. 10 shows a top view illustration of a magnetic field sensor according to the embodiment of FIG. 9A;

FIG. 11 shows an FEM simulation showing the magnetic field distribution of the magnetic field sensor of FIG. 10;

FIG. 12 shows an enlarged illustration of the section X from FIG. 11;

FIG. 13 shows a sensor according to an embodiment having a magnetic field sensor and an associated signal processing circuit;

FIG. 14A shows a sectional illustration of a magnetic field sensor for explaining the method for manufacturing the same; and

FIG. 14B shows a sectional illustration of a further sensor for explaining the method for manufacturing the same.

### DETAILED DESCRIPTION

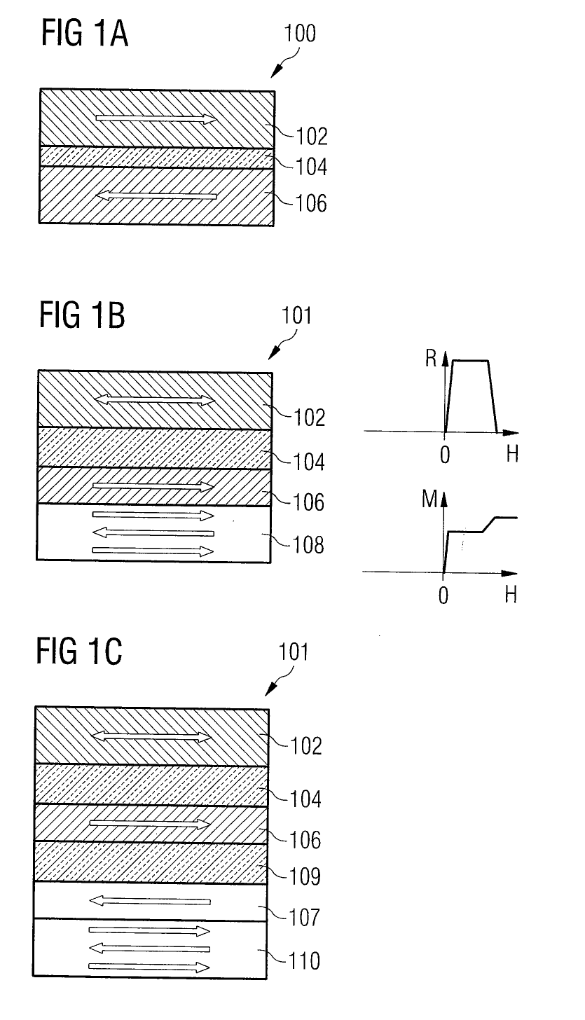

In the following, first of all the GMR structures are briefly explained. GMR structures are almost always operated in a so-called CIP configuration (CIP=current-in-plane), i.e. the applied current flows in parallel to the layer structure. In the GMR structures, several basic types exist, which prevail in practice. In practice, e.g. when used in automobile technology, in particular large temperature windows, e.g. from −40° C. to +150° C. and small field strengths of a few kA/m are necessary for an optimum and secure operation. The GMR structures most important for practical use are illustrated in FIGS. 1a-c.

The GMR structure illustrated in FIG. 1a shows the case of a coupled GMR system 100, in which two magnetic layers 102, 106, e.g. made of cobalt (Co), are separated by a non-magnetic layer 104, e.g. of copper (Cu). The thickness of the non-magnetic layer 104 is here selected such that without a magnetic field being applied, an antiferromagnetic coupling of the soft-magnetic layers 102, 106 is set up. This is to be illustrated by the indicated arrows. An exterior field then enforces the parallel alignment of the magnetization of the soft-magnetic layers 102, 106, whereby the resistance value of the GMR structure decreases.

The GMR structure illustrated in FIG. 1b shows a spin valve system 101 in which the non-magnetic layer 104 is selected with a thickness so that no coupling of the soft-magnetic layers 102, 106 results. The bottom magnetic layer 106 is strongly coupled to an antiferromagnetic layer 108, so that it is magnetically hard (comparable to a permanent magnet). The top magnetic layer 102 is soft-magnetic and serves as a measurement layer. It may be already magnetized by a small exterior magnetic field M, whereby the resistance value R is changed.

In the following, the spin valve arrangement 101 illustrated in FIG. 1b is explained in more detail. Such a spin valve structure 101 thus consists in a soft-magnetic layer 102 which is separated by a non-magnetic layer 104 from a second soft-magnetic layer 106 whose magnetization direction is fixed, however, by the coupling to an antiferromagnetic layer 108 by means of the so-called “exchange bias interaction”. The basic functioning of a spin valve structure may be illustrated using the magnetization and R(H) curve in FIG. 1b. The magnetization direction of the magnetic layer 106 is fixed in the negative direction. If now the exterior magnetic field M is increased from negative to positive values, then in the proximity of the zero crossing (H=0) the “free”, soft-magnetic layer 102 switches and the resistance value R steeply increases. The resistance value R then remains high until the exterior magnetic field M is large enough to overcome the exchange coupling between the soft-magnetic layer and the antiferromagnetic layer 108 and also switch the magnetic layer 106.

The GMR structure 101 illustrated in FIG. 1c is different from the GMR structure illustrated in FIG. 1b in that here the bottom antiferromagnetic layer 108 is replaced by a combination of a natural antiferromagnet 110 and a synthetic antiferromagnet 106, 107, 109 (SAF) located on top of same consisting of the magnetic layer 106, a ferromagnetic layer 107 and an intermediate non-magnetic layer 109. This way, the magnetization direction of the magnetic layer 106 is fixed. The top soft-magnetic layer 102 again serves as a measurement layer, whose magnetization direction may easily be rotated by an exterior magnetic field M. The advantage of the use of the combination of natural and synthetic antiferromagnets compared to the setup according to FIG. 1b is here the greater field and temperature stability.

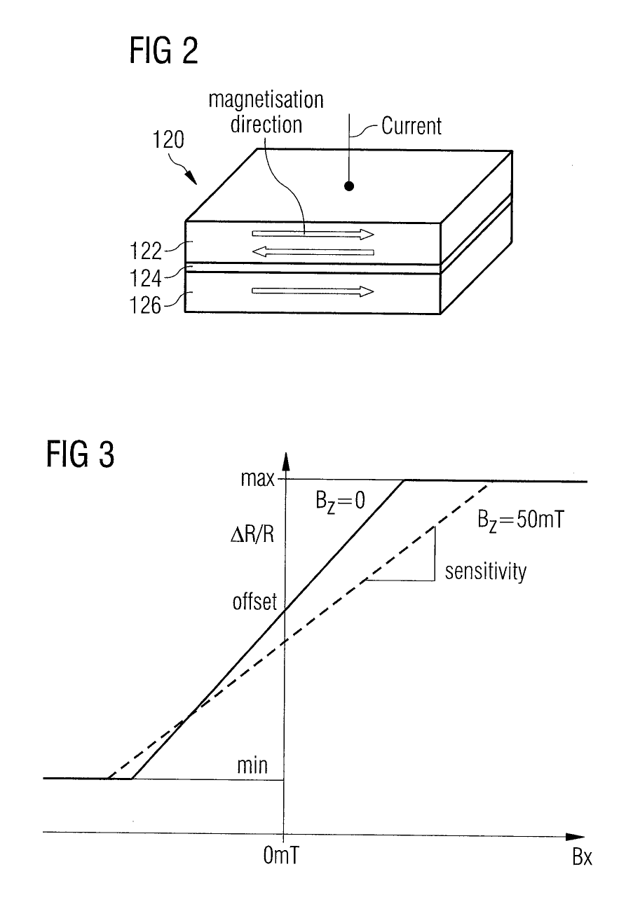

In the following, so-called TMR structures are explained generally. For TMR structures, the application spectrum is similar to the one of GMR structures. FIG. 2 now shows a typical TMR structure 120. The tunnel magnetoresistance TMR is obtained in tunnel contacts in which two ferromagnetic electrodes 122, 126 are decoupled by a thin insulating tunnel barrier 124. Electrons may tunnel through this thin barrier 124 between the two electrodes 122, 126. The tunnel magnetoresistance is based on the fact that the tunnel current depends on the relative orientation of the magnetization direction in the ferromagnetic electrodes.

The above different magnetoresistive structures (GMR/TMR) thus comprise an electric characteristic depending on an applied magnetic field, i.e. the specific resistance of an xMR structure of a magnetoresistive device is influenced by an influencing exterior magnetic field.

The above-described sensitive magnetic field sensors are present in the form of a chip and measure a magnetic field in the chip plane, i.e. in a plane in parallel to a surface of the chip. xMR sensors differentiate themselves by the fact that the same comprise a main sensitivity in exactly this chip plane in order to detect a magnetic field applied within this chip plane. With such xMR sensors, however, also a response to magnetic field components perpendicular to this plane may be observed, which may in particular be observed in a change of the sensitivity of the xMR sensor and in a change of the offset in a bridge interconnection of the xMR sensors.

FIG. 3 shows an illustration of the change of the offset and the sensitivity of an xMR sensor depending on a magnetic field operating also perpendicular to the detection plane. In FIG. 3, across the X axis one of the magnetic field components Bx is plotted which is to be detected by the xMR sensor. The other component which is not illustrated is the component By, so that the magnetic field is applied in the XY plane. Further, a magnetic field component Bz operating perpendicularly to this plane is plotted. The solid line in FIG. 3 shows the performance of the xMR sensor without a perpendicular magnetic field component Bz, and the dashed line shows the xMR sensor performance with a perpendicular magnetic field component Bz applied at the height of 50 mT. As it may be seen, the offset in the case of a perpendicularly acting magnetic component is shifted downwards and simultaneously the sensitivity decreases as it is indicated by the inclination of the straight line.

This performance leads to a corruption of the output signal of the xMR sensor which should preferably only contain signal portions which go back to the magnetic field existing in the chip plane which is just to be detected by the xMR sensor cells. The above-described change of the sensitivity of the xMR sensor is in the following also referred to as a transverse or cross-axis sensitivity with regard to a magnetic signal impinging perpendicularly to the chip plane, and, due to the corruption of the measurement results, this transverse sensitivity is disadvantageous. In particular in situations in which so-called back bias magnets (magnets for biasing the xMR sensor cell) are to be used in a sensor-gear-arrangement, this transverse sensitivity presents a substantial problem. The back bias signal here is perpendicular to the chip plane and changes with the distance from the gear to the sensor, whereby the useful signal which is actually to be measured is corrupted in the chip plane.

Further, integrated xMR angle sensors are known, set up in the form of a chip, wherein the xMR angle sensor consists of a sensor bridge which is sensitive with regard to an X component of the magnetic field and a sensor bridge which is sensitive with regard to a Y component of the magnetic field.

The above-described transverse sensitivity occurs with such an xMR angle sensor, if the magnetic field, which is usually provided by a permanent magnet, is not arranged absolutely in parallel and central above the xMR angle sensor chip. This leads to measurement errors which depend on a tilting or angular misalignment, respectively, and on the positional tolerance between the sensor and the magnetic field.

A further problem with such xMR sensors is that xMR sensor bridges also provide a signal if no magnetic field is applied. This phenomenon depends on the one hand on the manufacturing and the geometry of the xMR sensor and on the other hand it is also random, so that it may not definitely be guaranteed whether the output X, Y values are indeed valid or whether the magnetic field is not applied to the xMR sensor any more due to a malfunction in the overall arrangement.

According to one embodiment, the xMR sensor and the Hall sensor are arranged at least partially overlapping each other, preferably such that the Hall sensor is arranged to be aligned with the center of the xMR sensor.

Embodiments of the present invention relate to the combination of an xMR sensor and a Hall sensor, wherein the advantage of the Hall sensor is that the same only detects a magnetic field in one direction. For the case that the same is integrated in a chip, the Hall sensor only detects magnetic field components perpendicular to the surface of the chip, i.e. perpendicular to the chip plane. By the combination of xMR sensor and Hall sensor a measurement of the three-dimensional magnetic field direction is enabled, whereby the effect of The Bz signal in an xMR sensor may be compensated. Preferably, below each xMR sensor or below each group of xMR sensors additionally a Hall sensor is integrated, wherein the same is arranged such that only the magnetic field acting perpendicularly to the chip plane is detected. This enables that, based on the measurement signal obtained from the Hall sensor, a correction of the offset and/or the sensitivity of the xMR sensor signal in the chip plane may be achieved using a compensation circuit or a correction circuit.

It is the advantage of one embodiment that a substantially more accurate useful signal is obtainable with a simultaneously higher assembly position tolerances, which again contributes to a substantial reduction of the system costs. Further, only little additional chip area, approximately in the order of 25 μm², is required, as the Hall sensor may be integrated below the xMR sensor in the substrate. Additionally, a further advantage is the possibility of monolithic integration.

By the implementation according to this embodiment, thus by means of a Hall sensor integrated below the xMR sensor a signal is generated in order to compensate the transverse sensitivity of the xMR sensor with regard to the magnetic field impinging perpendicularly upon the chip plane.

Further, an alignment of the magnetic field sensor with regard to the magnetic field may be determined by using the output signal of the Hall sensor as a position signal when incorporating the magnetic field sensor. Depending on a position of the Hall sensor with regard to the xMR sensor and depending on a detected field strength at the Hall sensor, the position of the magnetic field sensor with regard to the magnetic field may be concluded. If the Hall sensor is, for example, arranged centrally with regard to the xMR sensor, when detecting a minimum output signal reflecting a minimum field detected by the Hall sensor, an optimum position of the magnetic field sensor and in particular of the xMR sensor with regard to the magnet may be detected.

Alternatively, knowing the position of the Hall sensor of the xMR sensor and with a decrease of the output signal of the Hall sensor, according to a decrease of the magnetic field, below a predetermined threshold, an optimum position of the xMR sensor with regard to the magnet may be detected. By this, a positioning accuracy of the magnetic field sensor in the assembly is enabled. Additionally or alternatively, by this also using a reference magnet, the positioning of the magnetic field sensor within the application module may be determined. The application module may then be positioned with corresponding marks for an assembly with regard to a magnet used in operation so that due to the accurate positioning of the magnetic field sensor within the module also an optimum positioning with regard to the magnetic field to be detected is given.

A further embodiment is a magnetic field sensor which, either instead of the centrally arranged Hall sensor or in addition to the same, comprises a plurality of further Hall sensors arranged offset to the center of the xMR sensor, preferably symmetrical to the center of the xMR sensor.

According to this embodiment, by the detection of the magnetic field by means of the one or the several additional Hall sensors, it may be securely determined whether the required magnetic field is applied, and thus it may also be guaranteed whether the obtained X, Y values with regard to the X, Y components of the magnetic field are valid. Further, according to this embodiment, an inhomogeneity of the field is detected by the Hall sensors and based on the result of the detection of an inhomogeneity also an error correction calculation may be performed, whereby based on the error correction an increase of the accuracy, for example of the angular accuracy of an xMR angle sensor, is achieved.

Again a further embodiment is a magnetic field sensor comprising the above-described functionality with regard to the detection of the presence of a magnetic field or the generation of a position signal, respectively, also with a magnetic field homogenous within the detection plane. The above-described embodiments of the present invention solve the problems indicated in the introduction of the description using the additional Hall sensor, which uses the curved field lines, for example of a permanent magnet, to measure a Z component. As far as such a Z component is present, by the detection of the same using the Hall sensor it may be guaranteed that the necessary magnetic field is applied and the X and Y values obtained by the xMR sensor are valid. If the magnetic field is completely plane or planar, respectively, with regard to the X, Y plane, this approach fails. For this reason, in this embodiment the magnetic field sensor is additionally equipped with means for redirecting the magnetic field, so-called field concentrators. In order to be able to detect a completely planar X, Y field with regard to its field strength using the Hall sensor, above the Hall sensor field concentrators are positioned in order to redirect the X, Y field components of the magnetic field into the Z direction. For this purpose, an additional, magnetic element may be provided causing a redirection of the magnetic field in a direction perpendicular to the chip surface, wherein here either an additional magnetic material is applied after the xMR sensor was generated on the substrate surface. Alternatively, the field concentrator may consist of the xMR material, so that merely a somewhat different structuring of the applied xMR material layer is required, no addition process step, however, like in the application of an additional element. Further, alternatively, the xMR sensor may act as a field concentrator, wherein here the Hall sensor and the xMR sensor are arranged such that the Hall sensor protrudes across the circumference of the xMR sensor.

According to this embodiment, by the redirection of the field lines a functionality according to the preceding embodiments is enabled even if a completely planar field is applied. Further, the approach according to this embodiment may also be employed in combination with the above-mentioned embodiment in order to additionally strengthen a magnetic field to be detected by the Hall sensor in order to thus enable a secure detection with regard to the presence of a magnetic field.

Further embodiments relate to a method and a sensor having a magnetic field sensor and a signal-processing circuit in order to generate, based on the output signals from the xMR sensor and the Hall sensor, a signal according to a magnetic field acting in the plane of the xMR sensor, and to perform the correction possibilities or generate the position information, respectively, mentioned in connection with the above-described embodiments. For generating the sensor with an evaluation circuit, preferably in addition to the first sensor structure the signal-processing circuit is generated within the substrate, wherein further preferably the sensor structures and the signal-processing circuit are generated by planar process steps.

The first sensor preferably is a magnetoresistive sensor, for example an xMR sensor which may, for example, be an AMR sensor, a GMR sensor or a TMR sensor. The second sensor preferably is a Hall sensor. Again preferably the two sensors are set up integrated, preferably using a planar process technology, on a common substrate.

A further embodiment is a method for determining whether a magnetic field is applied to a magnetic field sensor, wherein the magnetic field sensor includes a first sensor for detecting a magnetic field acting in a first plane and a second sensor for detecting a component of the magnetic field acting perpendicular to the plane, wherein a magnetic field component acting perpendicular to the plane is detected and a determination is made, based on a level of the magnetic field component detected perpendicular to the plane, whether the magnetic field is present.

Again a further embodiment is a method for determining a position of a magnetic field sensor with regard to a magnetic field, wherein the magnetic field sensor includes a first sensor for detecting a magnetic field acting in a first plane and a second sensor for detecting a component of the magnetic field acting perpendicular to the plane, wherein a magnetic field component acting perpendicular to the plane is detected and the position of the magnetic field sensor with regard to the magnetic field is determined based on a position of the second sensor with regard to the first sensor and on the level of the magnetic field sensor detected perpendicular to the plane.

One embodiment is a magnetic field sensor having a first sensor having an output for a first signal indicating a magnetic field acting in a plane, and a second sensor having an output for a second signal indicating a component of the magnetic field perpendicular to the plane, wherein the first sensor and the second sensor are applied on a common substrate by means of planar process steps.

One embodiment is a magnetic field sensor having a first sensor having an output for a first signal indicating a magnetic field acting in a plane, and a second sensor having an output for a second signal indicating a component of the magnetic field perpendicular to the plane, wherein the second sensor is arranged centrally with regard to the first sensor.

One embodiment is a magnetic field sensor having a first sensor having an output for a first signal indicating a magnetic field acting in a plane, a second sensor having an output for a second signal indicating a component of the magnetic field perpendicular to the plane, and a magnetic field concentrator arranged adjacent to the second sensor.

One embodiment is a magnetic field sensor having a first sensor having an output for a first signal indicating a magnetic field acting in a plane, and a second sensor having an output for a second signal indicating a component of the magnetic field perpendicular to the plane, wherein the first sensor and the second sensor are arranged non-overlapping.

One embodiment is an apparatus for detecting a magnetic field having a first means for detecting a magnetic field acting in a plane, and a second means arranged with reference to the first means to detect a component of the magnetic field perpendicular to the plane.

One embodiment is a sensor having a magnetic field sensor having a first sensor with an output for a first signal indicating a magnetic field acting in a plane, and a second sensor with an output for a second signal indicating a component of the magnetic field perpendicular to the plane, and a signal-processing circuit having a first input coupled to the output of the first sensor, a second input coupled to the output of the second sensor and having an output for an output signal indicating a magnetic field acting in the plane of the first sensor and corrected with reference to the magnetic field component acting perpendicular to the plane based on the signal applied to the second input.

One embodiment is a sensor having a magnetic field sensor having a first sensor with an output for a first signal indicating a magnetic field acting in a plane, and a second sensor with an output for a second signal indicating a component of the magnetic field perpendicular to the plane, and a signal-processing circuit having a first input coupled to the output of the first sensor, a second input coupled to the output of the second sensor and having an output for an output signal indicating, based on the signal applied to the second input, whether a magnetic field to be detected is present.

One embodiment is a sensor having a magnetic field sensor having a first sensor with an output for a first signal indicating a magnetic field acting in a plane, and a second sensor with an output for a second signal indicating a component of the magnetic field perpendicular to the plane, and a signal-processing circuit having a first input coupled to the output of the first sensor, a second input coupled to the output of the second sensor and having an output for a position signal, indicating, based on a position of the second sensor with regard to the first sensor and based on a signal applied to the second input, a position of the magnetic field sensor with regard to a magnet.

One embodiment is a sensor having a magnetic field sensor having a first sensor with an output for a first signal indicating a magnetic field acting in a plane, and a plurality of second sensors respectively having at least one output for a second signal indicating a component of the magnetic field perpendicular to the plane, and a signal-processing circuit having a first input coupled to the output of the first sensor, a plurality of second inputs coupled to the outputs of the second sensors and having an output for an output signal indicating, based on a mean value of the signals applied to the second inputs, whether a magnetic field to be detected is present.

One embodiment is a sensor having a magnetic field sensor having a first sensor with an output for a first signal indicating a magnetic field acting in a plane, and a plurality of second sensors respectively having at least one output for a second signal indicating a component of the magnetic field perpendicular to the plane, and a signal-processing circuit having a first input coupled to the output of the first sensor, a plurality of second inputs coupled to the outputs of the second sensors and having an output for an output signal indicating, based on the differences of the signals applied to the second inputs, an inclination of the magnetic field with regard to the magnetic field sensor.

In the following, embodiments of the present invention are explained in more detail with reference to a combination of a GMR sensor and a Hall sensor. The present invention is not limited to this, however. Rather, the concept may be applied to a combination of a first sensor detecting a magnetic field in a plane, and a second sensor, detecting a magnetic field only in one direction perpendicular to the plane. Instead of the GMR sensor, e.g. another magnetoresistive sensor may be used, e.g. a so-called xMR sensor, like e.g. an AMR sensor (AMR=anisotropic magnetoresistance), a GMR sensor (GMR=giant magnetoresistance), a CMR sensor (CMR=colossal magnetoresistance), an EMR sensor (EMR=extraordinary magnetoresistance) or a TMR sensor (TMR=tunnel magnetoresistance). Further, other sensors having magnetoresistive structures or spin valve sensors may be used.

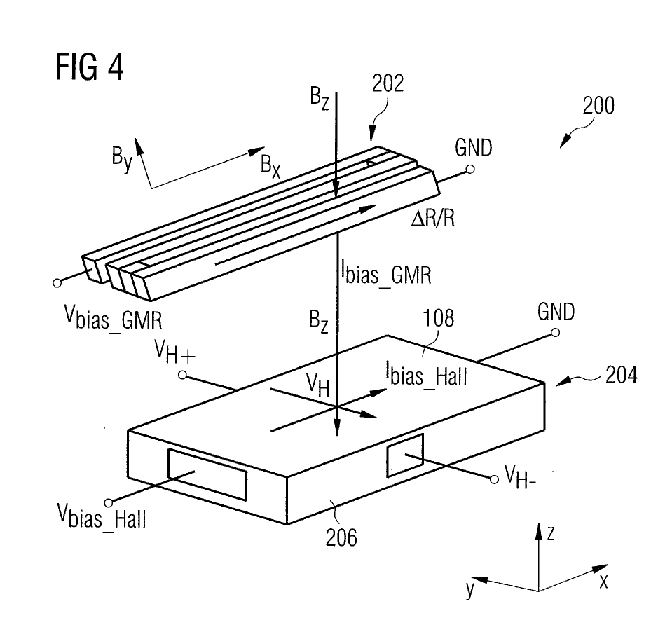

FIG. 4 shows an embodiment of the magnetic field sensor which is designated in its entirety by the reference numeral 200. The magnetic field sensor 200 includes a GMR sensor 202 which is constructed in a conventional way and connectable at one end to a ground terminal GND, and receives a GMR sensor bias Vbias_GMR at another end. Further, the magnetic field sensor 200 includes a Hall sensor 204, which is formed in a substrate 206 in the embodiment shown in FIG. 4. Along the X direction, the Hall sensor 204 is connected to ground GND at one terminal and to a Hall bias voltage Vbias_HALL at the other terminal. Transverse to the X direction, via two electrodes the Hall potential VH+ and VH− is tapped. On a surface 208 of the substrate 206 the GMR sensor 202 is arranged, wherein in FIG. 4 for reasons of illustration the GMR sensor is shown spaced apart from the Hall sensor, preferably those two sensors are arranged on top of each other, however. Depending on the circumstances, the GMR sensor is either arranged on the top surface 208 or on the opposing surface of substrate 206.

In FIG. 4, further the different directions of the magnetic field are shown, on the one hand the magnetic field components Bx and By, wherein Bx is the useful signal to be measured in the chip plane, measured by the change of resistance ΔR/R of the GMR sensor 202. Bz is the interfering magnetic field component present perpendicular to the chip plane or the substrate surface 208 or a back bias magnetic field of a differential sensor arrangement. While the GMR sensor generates an output signal due to its transverse sensitivity, depending apart from the magnetic field components in the chip plane, i.e. the components Bx and By, also on the perpendicular component, i.e. the component Bz, the Hall sensor only enables the detection of the component perpendicular to the chip plane 208, i.e. the Bz component.

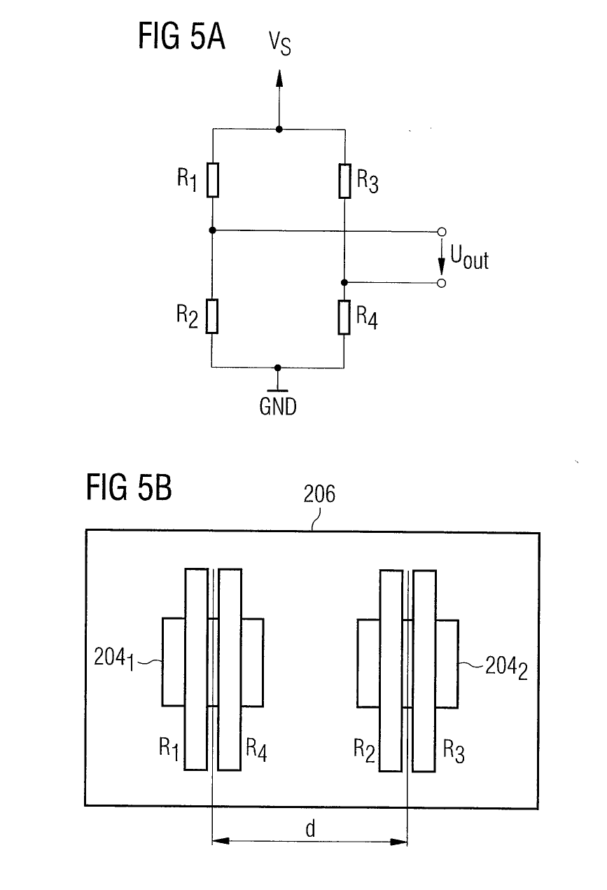

FIG. 5 shows a GMR bridge having Hall sensors for a transverse sensitivity compensation, wherein FIG. 5(a) shows the four GMR sensors R1 to R4 connected between ground GND and a supply voltage Vs. At the bridge output, the signal UAUS is output. FIG. 5(b) shows the arrangement of the four GMR sensors together with two Hall sensors 204, and 204₂ on a common substrate 206, wherein the respective sensor arrangements comprise a distance d. As it may be seen from FIG. 5(b), the GMR sensors and the respectively associated Hall sensor are arranged at least partially overlapping each other, so that magnetic field lines in the direction perpendicular to the chip plane, which penetrate the GMR sensors, are also detected by the associated Hall sensors in order to guarantee that also those magnetic field components are detected by the Hall sensor which have a negative influence on the output signal/useful signal of GMR sensors R1 to R4. Although basically also an arrangement of the Hall sensors in a non-overlapping way with the GMR sensors would be possible, the above-described implementation is preferred in order to guarantee an efficient and secure compensation of the transverse sensitivity of the sensors.

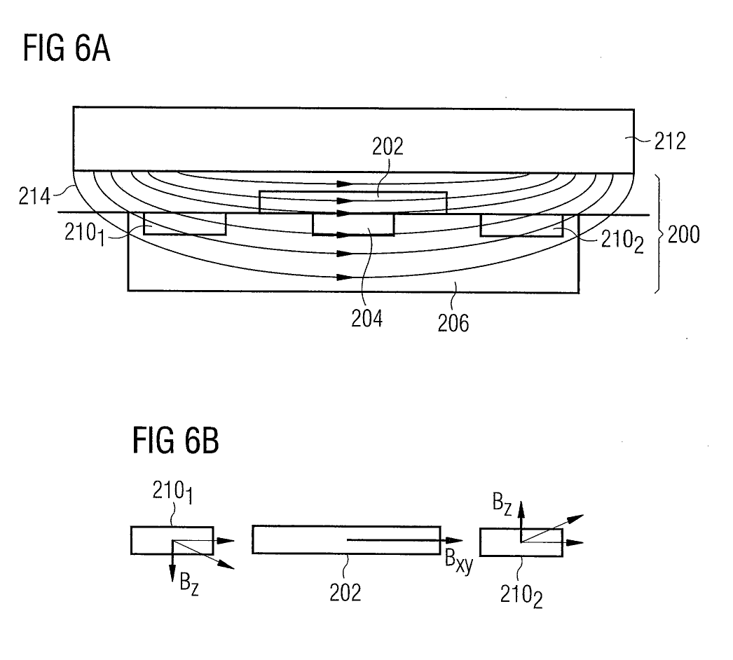

With reference to FIG. 6, in the following the further embodiment of the present invention is explained in more detail. FIG. 6(a) shows a cross-sectional view of integrated Hall sensors in an integrated GMR sensor with an optimum alignment between the sensor and the magnet. FIG. 6(a) shows the sensor 200 with the substrate 206 on whose top surface the GMR sensor 202 is arranged. In the substrate 206 three Hall sensors 204, 210₁ and 210₂ are shown. Further, the magnet 212 and the magnetic field lines 214 originating from the same are shown. As it may be seen, the magnetic field sensor 200 according to the embodiment of FIG. 6(a) includes additional magnetic field sensors 210₁ and 210₂, which are arranged offset with regard to a center of the GMR sensor structure. In the indicated embodiment, the sensors 210₁ and 210₂ are arranged in addition to the Hall sensor 204 arranged centrally with regard to the GMR sensor structure. In connection with this embodiment it is to be noted, however, that the present invention is not limited to the embodiment shown in FIG. 6. Rather, according to this embodiment, the central Hall sensor 204 may also be omitted.

FIG. 6(b) schematically shows the distribution of the magnetic field components detected by the individual sensors 210₁, 210₂ and 202, and, as it may be seen, the GMR sensor only detects the magnetic field components BX and BY lying within the chip plane, whereas the Hall sensors detect the components BZ. As it may further be seen from FIG. 6(b), the amount of the signal amplitudes BZ of the two Hall sensors 210₁ and 210₂ is equal.

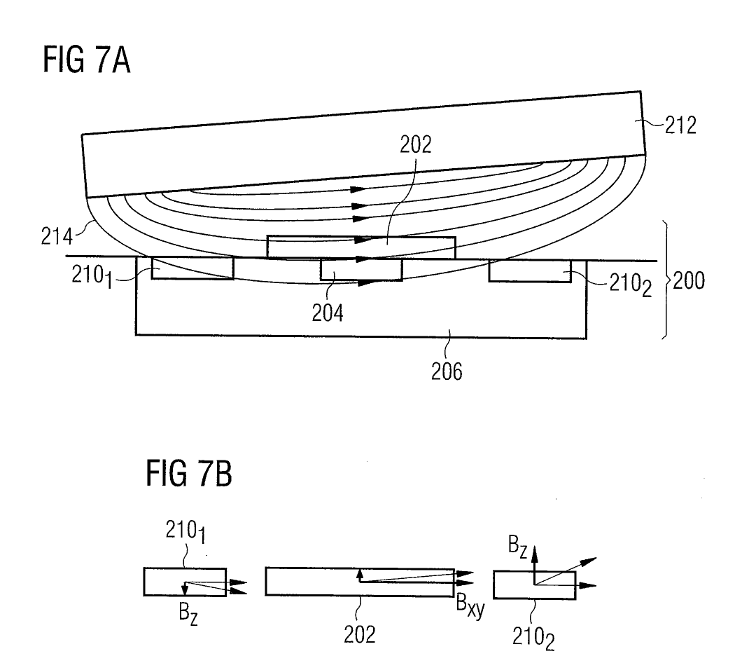

FIG. 7(a) shows the sensor structure 200 from FIG. 6(a), wherein in contrast to FIG. 6(a) the sensor 200 and the magnet 212 are arranged inclined to each other, which has the consequence, as it may be seen from FIG. 7(b), that the signal amplitudes BZ of the two Hall sensors are not equal any more.

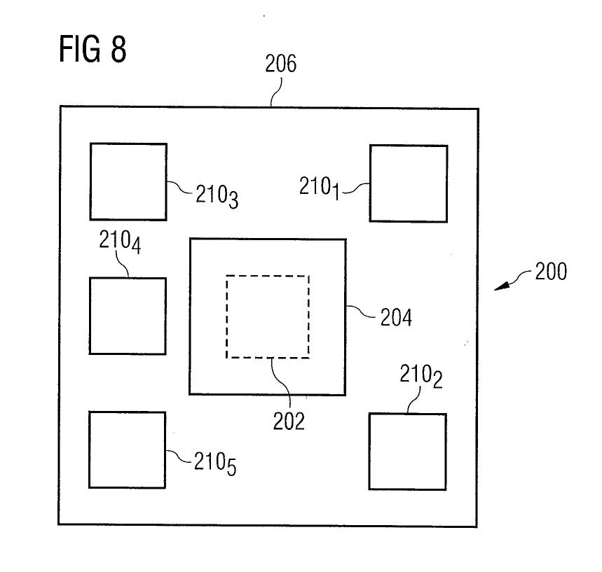

FIG. 8 shows a top view illustration of a magnetic field sensor 200 according to the embodiment of FIG. 6 in a further implementation. As it may be seen from the top view illustration, the sensor 200 includes the substrate 206 in which a plurality of Hall sensors 210₁ to 210₅ is formed, which are arranged offset with regard to a center of the GMR sensor 202 such that GMR sensor and Hall sensors are arranged non-overlapping. Further, the optional Hall sensor 202 is shown. Instead of the arrangement shown in FIG. 8, the sensor 210₄ might also be omitted or another, differently implemented symmetrical arrangement of the Hall sensors may be selected, wherein the present invention is not limited to a symmetrical arrangement of Hall sensors, however.

The magnetic field sensor 200 according to a further embodiment shown with reference to FIGS. 6 to 8 forms an integrated GMR sensor with additional integrated Hall sensors 210₁ to 210₅ which serve to measure the strength of a magnetic field into a direction perpendicular to the chip surface, wherein it is substantial, as mentioned above, that the GMR sensors react to magnetic fields in the X, Y plane, whereas the Hall sensors 210₁ to 210₄ only react to the Z component of the magnetic field.

Preferably, in a use of the magnetic field sensors according to the further embodiment, a magnetic field 214 is generated by a small magnet 212, so that the magnetic field 214 is not completely homogenous in the X, Y plane, but rather the field lines, as it may be seen from FIGS. 6(a) and 7(a), are curved. The curvature is naturally stronger the smaller the planar magnet surface is. In this case it is sufficient to place planar Hall elements not directly below the GMR sensor but somewhat apart from the magnetic center.

As noted, these Hall sensors measure the corresponding Z components of the magnetic field, whereby a corruption of measurement signals is prevented in a detection of a magnetic field in a detection plane.

This further embodiment has a plurality of advantages, in particular in the application of the magnetic field sensors. Thus, in security-relevant systems the omission of the output signal of the GMR sensor or a corruption of the same, respectively, due to a malfunction may also be measured easily, also online, and over the whole life duration. In other words this means that, based on the output signals of the magnetic field sensor, a corresponding evaluation may be performed guaranteeing its correct operation during the complete use of the sensor, so that you do not only depend on the correct assembly according to predetermined tolerances but have a continuous possibility of inspection.

The above optionally described, centrally positioned Hall sensor 204 is used in systems in which an accurate positioning of magnet to GMR sensor is required, as hereby an optimum, aligned position of magnet and sensor with respect to each other may be detected with a minimum value of the magnetic field component Bz acting perpendicular to the chip plane. Additionally, by a detection of the field strength at the individual Hall sensors the positioning accuracy of the sensor within the overall module may also generally be controlled.

A corruption of measurement signals in the detection of a magnetic field in a detection plane is prevented by measuring the magnetic field using the Hall sensors in order to be able to detect the absence of a magnetic field in the error case. Further, based on the measurement results in the measurement of the magnetic field using Hall sensors an error correction calculation may be performed in order to increase the angle measurement accuracy of the GMR angle sensors.

As mentioned above, a Hall sensor in an arrangement as is shown with reference to FIGS. 6, 7 and 8 is only sensitive in the Z component of the magnetic field, not with regard to the magnetic field acting in the X, Y direction, however.

Using a Hall sensor, for example the sensor 210₁, a Z component of the magnetic field at a point outside the center of the magnet is measured as also there a Z component results due to the inhomogeneity of the magnetic field. Based on the output signal of this Hall sensor it may then be detected whether a magnetic field is indeed present or not, i.e. whether a required magnet is still present.

As with the first-mentioned embodiment, the sensor 204 may be provided in the middle of the magnet below the GMR sensor in order to calculate the Z component of the magnetic field in an error correction calculation from the output signal of the GMR sensor.

According to a further implementation of the further embodiment, the Z components of the magnetic field are detected via the plurality of Hall sensors 210₁ to 210₅ at several points outside the center of the magnet, i.e. at positions spaced apart from the GMR sensor. Thus, on the one hand a middle magnetic field is determined which is again used to assess whether a magnet is present at all. On the other hand, an error correction may be performed via the determined field strengths.

The mean value of the amounts of all field strengths of the Hall sensors represents the strength of the magnetic field applied from the outside and via this strength it may be determined whether a magnetic field is present at all.

The differences of the field strengths between the individual Hall sensors represent an inclined position of the magnetic field with regard to the GMR sensor, wherein these values may be used for an error correction of the output signal of the GMR sensor.

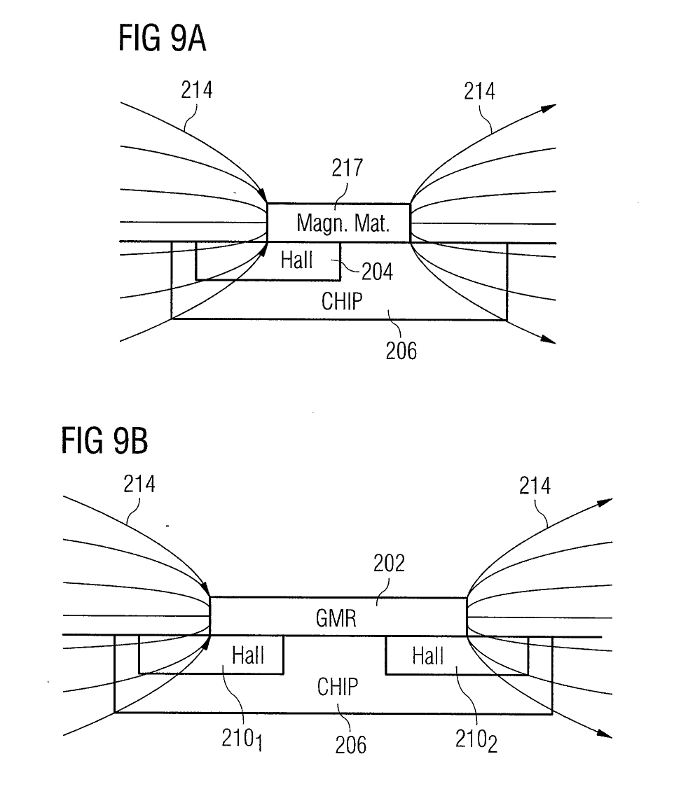

In the following, with reference to FIGS. 9 to 12, again a further embodiment of the present invention is explained in more detail. In the above-described embodiments of the present invention it was assumed that the Hall sensor reacts to a field component of the applied magnetic field acting perpendicular to the substrate surface in order to hereby detect a correction of the output signal of the GMR sensor or further information regarding the position of the sensor with regard to the magnetic field, respectively. By this detection with the help of the Hall sensor it may be guaranteed that it is detected whether the required magnetic field is applied and the output X, Y values are valid. If a homogenous magnetic field exists in the X, Y direction, however, the additional Hall sensor, which is only sensitive with regard to the Z component of the magnetic field, generates no output signal. In order to solve this problem, according to this embodiment a means for redirecting the field components is provided in order to redirect the X, Y field components at least partially into the Z components.

FIG. 9a shows a first implementation of the further embodiment wherein a section of the magnetic field sensor is shown (without GMR sensor). The Hall sensor 204 is set up integrated in the substrate 206 (chip), and arranged on a surface of the substrate 206 is a field concentrator 217 of a suitable magnetic material which is in the illustrated example arranged partially overlapping the Hall sensor 204. The field lines are designated by the reference numeral 214. As it may be seen, by the provisioning of the field concentrator 217 a redirection of the field components acting in the X,Y level into the Z direction takes place, so that the same may be detected by the Hall sensor 204. The separate field concentrator made of magnetic material shown in FIG. 9a is applied later. Alternatively, the field concentrator 217 may be manufactured from a GMR material which is used in the manufacturing of the GMR sensor anyway, so that here in the manufacturing e.g. only one changed structuring mask is required for structuring the GMR material, and no additional process steps. The field concentrator is in this case generated in the same manufacturing step as the GMR sensor.

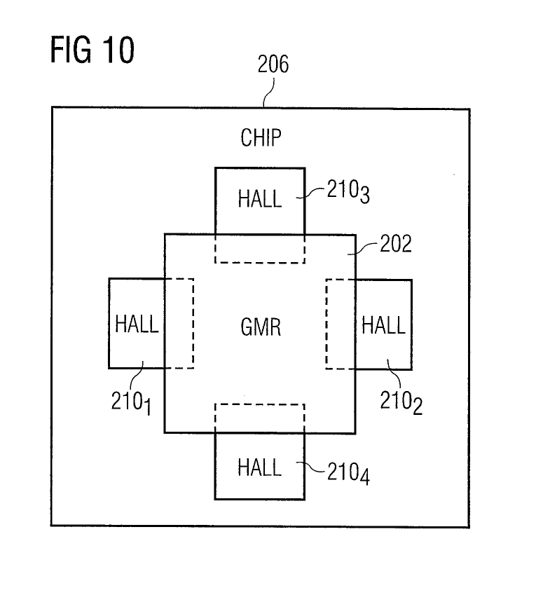

FIG. 9b shows an alternative implementation in which the GMR sensor 202 itself is operable as a field concentrator. As it is shown in FIG. 9b, in the chip 204 a first Hall sensor 210₁ and also a second Hall sensor 210₂ are arranged. On the chip surface, the GMR sensor 202 is arranged, and the field lines are again designated by the reference numeral 214. In the example in FIG. 9b, the Hall sensors are arranged with reference to the circumference of the GMR sensor so that the sensors 210₁ and 210₂ protrude beyond the exterior circumference of the GMR sensor, as it may more clearly be seen in the top view illustration 210, wherein here further the additional Hall sensors 210₃ and 210₄ are visible. In the example shown in FIG. 9b and in FIG. 10, the field concentrator 217 is formed by the measurement GMR sensor itself. Thus, no additional magnetic structure is required, as the present GMR sensor, apart from measuring the X,Y field components, also causes a redirection of the components into the Z direction, and thus serves as a field concentrator.

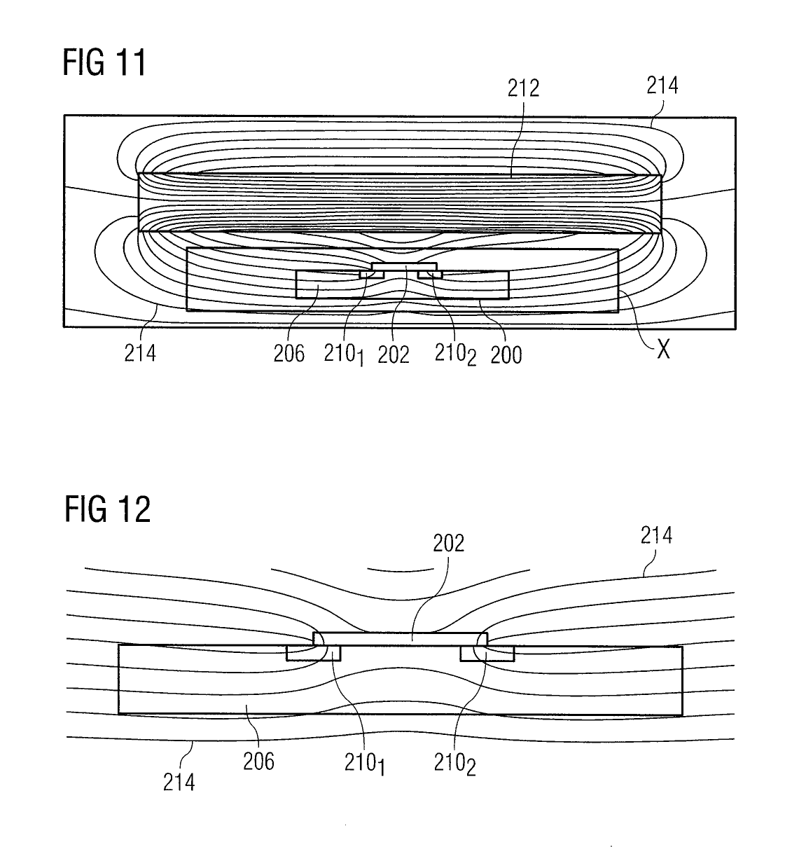

The effect of the GMR sensor as a field concentrator for redirecting the X,Y component of the magnetic field into the Z component for a secure detection by the Hall sensors is again shown in FIG. 11 with reference to an FEM simulation, showing a sectional illustration of a sensor 200 and the associated magnets 212. The section shown enlarged in FIG. 12 is designated by X. As it may clearly be seen from FIG. 12, here a corresponding redirection of the field component from the X,Y level into the Z level is performed.

Thus, by the arrangement of an additional field concentrator according to FIG. 9a or by the arrangement of GMR sensor and Hall sensor relative to each other shown in FIG. 9b, it is guaranteed that also with a completely planar magnetic field a redirection of the planar components into the Z level takes place in order to hereby guarantee a detection by the Hall sensor.

In addition it is noted, that the embodiment described with reference to FIGS. 9 to 12 is not limited to a use of a magnetic field sensor with a purely planar implementation of the magnetic field. Rather, this approach may also be used in the above embodiments in order to cause an amplification of the output signal of the Hall sensor by again amplifying the field concentration in the Z level, and thus a secure output signal at the Hall sensor may be generated.

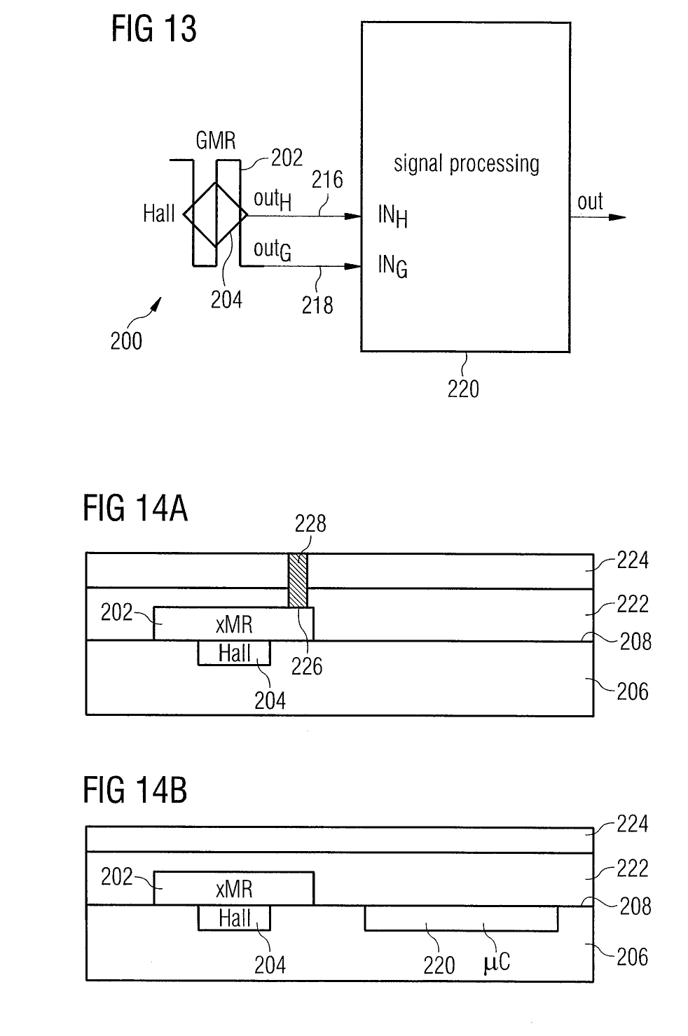

FIG. 13 schematically shows a sensor with the magnetic field sensor 200 consisting of the GMR sensor 202 and the Hall sensor 204, wherein the output signals from the outputs OUT_{G} and OUT_{H} of the two sensors are output via lines 216 and 218 to the inputs EIN_{G} and EIN_{H} of a signal processing circuit 220, which in turn outputs a corrected signal, a position signal and/or an error signal at the output OUT. Although in FIG. 13 an example is shown in which the signal-processing circuit is connected to a magnetic field sensor according to the embodiment described with reference to FIGS. 4 and 5, the sensor may also include a magnetic field sensor according to embodiments described with references to FIGS. 6 to 11.

If the signal-processing circuit is used together with a magnetic field sensor according to the embodiment described with reference to FIGS. 4 and 5, then the signal-processing circuit is further configured to compensate the output signal of the GMR sensor with reference to the magnetic field component acting perpendicular to the plane based on the output signal of the Hall sensor and/or to determine, based on the output signal of the Hall sensor, whether a magnetic field to be detected is present or not.

If the signal-processing circuit 220 is used together with a magnetic field sensor according to the embodiments described with reference to FIGS. 6 to 11, then the signal-processing circuit is further configured to generate, based on the output signals of the plurality of Hall sensors, a mean value of the amounts of the field strengths detected by the Hall sensors and to determine, based on the mean value, whether a magnetic field to be detected is present. Additionally or alternatively, the signal-processing circuit may in this case be configured to determine, based on the output signals of the Hall sensors, differences of the field strengths detected by the individual Hall sensors and to determine, based on those differences, an inclination of the magnetic field with reference to the magnetic field sensor, wherein the signal-processing circuit may further be configured to generate an error signal based on the detected differences or to correct the output signal of the GMR sensor based on the detected differences.

For the case that a Hall sensor is arranged centrally with regard to the GMR sensor, as it may be the case in the above embodiments, the signal-processing circuit is additionally configured to generate a position signal based on the output signal of the Hall sensor which indicates a position of the magnetic field sensor with regard to a magnet generating the magnetic field to be detected.

Further, an alignment of the magnetic field sensor with regard to the magnetic field may be determined by using the output signal of the Hall sensor as a position signal when incorporating the magnetic field sensor. Depending on a position of the Hall sensor with regard to the xMR sensor and depending on a detected field strength at the Hall sensor, the position of the magnetic field sensor with regard to the magnetic field may be concluded. If the Hall sensor is, for example, arranged centrally with regard to the xMR sensor, then, when detecting a minimum output signal reflecting a minimum field detected by the Hall sensor, an optimum position of the magnetic field sensor and in particular of the xMR sensor with reference to the magnet may be detected.

With reference to FIG. 14 now an embodiment for an integrated magnetic field sensor and an integrated sensor (magnetic field sensor and signal-processing circuit) and for manufacturing the same is described.

FIG. 14a shows a schematical sectional view through a magnetic field sensor of the present invention. The magnetic field sensor includes the semiconductor substrate 206, e.g. of silicon material, having a first main surface 208, wherein a Hall sensor structure 204 adjacent to the main surface 208 of the semiconductor substrate 206 is integrated into the same in a known way. According to the embodiments of the present invention, the Hall sensor structure 204 integrated into the semiconductor substrate 206 may basically be manufactured using any MOS and bipolar technologies or combinations of those technologies (BiCMOS processes), respectively. Those method steps typically result in a final passivation step, in which the wiring levels required for wiring the electric components of the Hall sensor(s) 204 are covered with an electrically insulating passivation layer, e.g. manufactured from silicon oxide or nitride, except for desired contact holes. Thus, the main surface 208 is typically defined by the surface of the electrically insulating passivation layer (not shown in FIGS. 14a-b).

On the main surface 208 of the semiconductor substrate 206 now the magnetoresistive sensor structure 202 is applied, e.g. in the form of a GMR sensor structure, by means of planar process steps. Possible layer sequences of the GMR structure are e.g. illustrated in the FIGS. 1a)-1c) and in FIG. 2. The thickness of the magnetoresistive sensor structure 202 is in the range of approximately 2 to 200 nm and preferably in a range of around 50 nm. Within the scope of the present description, magnetoresistive structures or sensor structures, respectively, include all xMR structures, i.e. in particular AMR structures (AMR=anisotropic magnetoresistance), GMR structures (GMR=giant magnetoresistance), CMR structures (CMR=colossal magnetoresistance), EMR structures (EMR=extraordinary magnetoresistance) and TMR (TMR=tunnel magnetoresistance), as well as magnetoresistance structures and spin valve structures. It is to be noted that the above enumeration is not exclusive.

Further, it is noted, that the method was only explained with reference to a single magnetic field sensor, the method may, however, simultaneously be applied for a mass production of such magnetic field sensors at the wafer level. Further, a plurality of Hall sensors may be formed, as it was described above with reference to the embodiments.

Before the further steps for manufacturing are described, first of all a manufacturing method for a sensor, i.e. an integrated magnetic field sensor having a signal-processing circuit, is explained with reference to FIG. 14b. The basic difference to FIG. 14a is that, in addition to the Hall sensor(s), the signal-processing circuit 220 is integrated in the substrate 206, as it is schematically shown in FIG. 14b. The signal-processing circuit 220 is integrated such that the same is electrically connected to the Hall sensor(s) 204 and preferably also to the GMR sensor (202), so that the above-described functionality for correcting the output signal of the GMR sensor or for detecting the other described signals, respectively, may be performed. Contacting the GMR sensor 202 with the signal-processing circuit 220 may, for example, take place by means of a conventional through-contacting, connecting the GMR sensor 202 to a wiring level of the signal-processing circuit 220.

FIG. 14b shows a schematical sectional illustration through a sensor according to the embodiments of the present invention. The sensor includes a semiconductor substrate 206, e.g. made of silicon, having a first main surface 208, wherein a Hall sensor structure 204 and a semiconductor circuitry 220, adjacent to the main surface 208 of the semiconductor substrate 206, is integrated basically by means of any MOS and bipolar technologies or combinations of those technologies (BiCMOS processes), respectively, into the same, wherein the integrated circuitry 220 may comprise both active devices like transistors and also passive devices like diodes, resistances and capacitors as well as the wiring of those components.

Like in the embodiment described above with reference to FIG. 14a, it is noted also here that the method was only explained using one sensor, that the method may, however, also be applied for a mass production of such sensors at the wafer level. Further, a plurality of Hall sensors may be formed, as described above with reference to the embodiments.

In the following, reference is made as an example to a CMOS base process. In a CMOS base process, first the p or n wells, respectively, for generating the substrate areas of the n-channel or p-channel MOS transistors, respectively, are manufactured (well process module). In the process sequence, the insulation of neighboring transistors follows by generating a so-called field oxide between the transistors. In the so-called active areas, i.e. those regions which are not covered by the field oxide, subsequently the MOS transistors result. Thus, the front part of the overall process providing the transistors and their respective mutual insulation is completed. It is also referred to as FEOL (=front end of line). In the BEOL part (BEOL=back end of line) now the contacting and connecting of the individual mono- or polycrystalline semiconductor areas (e.g. silicon areas) of the FEOL part is performed according to the desired integrated circuitry 220.

For contacting and connecting the semiconductor areas at least one metal sheet, wherein frequently also two and more metal sheets are used, is required, wherein this case is referred to as a multi-sheet metallization. The process is completed by passivation, which is to protect the integrated circuit against mechanical damages due to environmental influences and against the penetration of foreign matter.

With a progressive reduction of structure with a simultaneously increasing thickness of the overall layer setup, the leveling of surfaces with steep stairs plays an ever greater role, so that also according to the embodiments of the present invention leveling methods may be required, for example, to obtain surfaces of the different levels as plane as possible, like e.g. the metal sheet(s) or the insulation layers and thus of the magnetoresistive structure 202.

On the surface 208 of the substrate 206, the magnetoresistive sensor structure is arranged. The thickness of the magnetoresistive sensor structures 202 is in the range of approximately 2 to 200 nm and preferably in a range of approximately 50 nm. As mentioned above, magnetoresistive structures or sensor structures, respectively, include all xMR structures, i.e. in particular AMR structures (AMR=anisotropic magnetoresistance), GMR structures (GMR=giant magnetoresistance), CMR structures (CMR=colossal magnetoresistance), EMR structures (EMR=extraordinary magnetoresistance) and TMR (TMR=tunnel magnetoresistance) as well as magnetoresistance structures and spin valve structures. It is to be noted, that the above enumeration is not exclusive.

In order to now protect the magnetic field sensor or the sensor, respectively, having the integrated circuitry 220, the integrated Hall sensor 204 and the magnetoresistive sensor structure 202, illustrated in FIG. 14a or in FIG. 14b, respectively, against corrosion and mechanical damage, after structuring or after the structural application of the magnetoresistive sensor structure 202 optionally a passivation layer arrangement 222/224 may be applied which is only opened at those locations at which contact locations 226 are to be contacted. The passivation layer arrangement 222 may, for example, consist of an oxide, e.g. plasma oxide, or a nitride, e.g. plasma nitride, having respectively a layer thickness of approximately 0.1 to 5 μm and preferably of approximately 0.5 to 1 μm. Thus, also double layers of oxide and/or nitride materials using the above layer thicknesses are conceivable.

The proceedings for manufacturing a magnetic field sensor or a sensor, respectively, according to the embodiments of the present invention may thus be summarized as follows. The basic process of the semiconductor base manufacturing process is executed up to the manufacturing of the Hall sensor structure 204 (FIG. 14a) or the Hall sensor structure 204 and the semiconductor circuitry 220 (FIG. 14b), respectively. An annealing of the device present then may (if required) be performed by an annealing step, e.g. with temperatures of 150 to 350° C.

On the surface 208 of the substrate 206 the magnetoresistive sensor structure 202 is applied and patterned. Finally, optionally the passivation arrangement 222/224 is applied, for example comprising an oxide/nitride passivation layer 222 and an additional passivation layer 224 of a photoimide material. At that point of time, also here an additional annealing process may take place, which should be compatible with the already applied magnetoresistive sensor structure, however. Finally, terminal pads 226 are opened using the standard process of the base manufacturing process and filled with a conductive material 228, so that the contact location 226 and, if applicable, further contact locations for contacting the Hall sensor structure 204 and/or the integrated circuit 220 may be connected to a lead frame of a package housing.

From the manufacturing method described with reference to FIG. 14 it becomes clear that the magnetoresistive sensor structure may be integrated in a process for manufacturing the Hall sensor structure 204 or the Hall sensor structure 204 and the semiconductor circuitry 220, respectively. The contacting of the magnetoresistive sensor structure may be achieved from the bottom (with reference to the magnetoresistive sensor structure in the direction of the semiconductor substrate) by the use of a standard inter-metal contact process (i.e., e.g., W plugs). Further a contacting of the magnetoresistive sensor structure 202 may be achieved from the top either through an additional metal layer or through an addition metal contact.

In addition to that, the manufacturing method is advantageous in so far as a surface, for example planarized using a CMP proceeding and which is correspondingly conditioned, is used as a starting point and growth support for the magnetoresistive sensor structure which is preferably implemented as an xMR layer stack. Thus, according to the embodiments of the present invention, a magnetoresistive sensor structure integrated with a Hall sensor structure/active circuitry may be obtained.

As it becomes clear from the above disclosures, it is advantageous for costs and performance reasons, to integrate the magnetoresistive sensor structure and the Hall sensor structure together with the evaluation/control electronics on the semiconductor circuit substrate (vertically). For a maximum compatibility with the manufacturing process it is required to further enable a vertical integration, i.e. to position the magnetoresistive sensor structures above the integrated electronic semiconductor circuitries, as well as to implement a partially required additional passivation with a photosensitive polyimide. The polyimide material is frequently a very important component to clearly improve the adhesion between the housing and the chip surface. The polyimide material is here typically between 2.5 μm and 6 μm thick.

The manufacturing method thus offers a series of advantages. Thus, the method may be integrated with an active semiconductor circuitry with slight adaptations in each semiconductor base manufacturing process. The magnetoresistive sensor structure applied here relies on a surface which is planar and to be conditioned independent of the semiconductor base manufacturing process. Thus, the ideal planar contact area enables an extremely robust and reliable contacting of the magnetoresistive sensor structure, i.e. the xMR layer systems, between the magnetoresistive sensor structure and the contact pads. Problems like breaks, thinnings, etc. are prevented. Further, the active sensor layer, i.e. the magnetoresistive sensor structure is not changed by an etching process from the top.

Due to the reduced thickness of the magnetoresistive sensor structures in a range of approximately 2 to 200 nm and preferably in a range of approximately 50 nm, further the final passivation using the passivation arrangement 222 and/or the addition passivation layer 224 sits on a substantially planar surface and is thus sealed in a large process window. Optionally, it is further possible that the last inter-metal connections (via) of the semiconductor base manufacturing process are used as a sensor terminal, i.e. as a terminal of the magnetoresistive sensor structure.

In addition to that, in the manufacturing method the final annealing process for the integrated process, i.e. the semiconductor base manufacturing process, and for the magnetoresistive sensor module, may take place independently, so that in particular the annealing process to be performed with a lower temperature may be performed later for the sensor module without the other integrated circuit parts being damaged, and on the other hand the annealing process, which takes place at high temperatures, may be performed for the remaining integration before the generation of the sensor module, so that no impairment or damage, respectively, of the sensor module occurs.

Thus it becomes clear that for the manufacturing method planar process steps and basically only standard semiconductor manufacturing processes are required. The resulting magnetic field sensor or sensor, respectively, may be placed on the active integrated semiconductor circuit in a space-saving way, wherein in this connection this is referred to as a vertical integration.

It is further to be noted that the described method for the integration of magnetoresistive sensors with Hall sensors in a silicon substrate may also be used, with corresponding adaptations, for an integration of magnetoresistive sensors with Hall sensors in a GaAs substrate.

The sensors are applied in all fields of technology in which the magnetic field may serve as an information carrier, i.e., e.g., in automobile technology, in mechanical engineering/robotics, in medical technology, in non-destructive materials testing and in micro-system technology. Using the sensors, a plurality of different mechanical parameters are detected, like e.g. position, speed, angularity, rotational speed, acceleration, etc., but also current flow, wear and tear or corrosion may be measured.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A magnetic field sensor, comprising
a first sensor comprising an output for a first signal indicating a magnetic field acting in a plane; and
a second sensor comprising an output for a second signal indicating a component of the magnetic field perpendicular to the plane,
wherein the first sensor and the second sensor are applied on a common substrate by means of planar process steps.

2. A magnetic field sensor according to claim 1, wherein the first sensor is a magnetoresistive sensor and the second sensor is a Hall sensor.

3. A magnetic field sensor, comprising
a first sensor comprising an output for a first signal indicating a magnetic field acting in a plane; and
a second sensor comprising an output for a second signal indicating a component of the magnetic field perpendicular to the plane.

4. A magnetic field sensor according to claim 3, wherein the first sensor is a magnetoresistive sensor.

5. A magnetic field sensor according to claim 4, wherein the magnetoresistive sensor is an AMR sensor, a GMR sensor, a CMR sensor, an EMR sensor or a TMR sensor.

6. A magnetic field sensor according to claim 3, wherein the second sensor is a Hall sensor.

7. A magnetic field sensor according to claim 3, wherein the first sensor and the second sensor are arranged at least partially overlapping each other.

8. A magnetic field sensor according to claim 7, wherein the second sensor is arranged to be aligned with the center of the first sensor.

9. A magnetic field sensor according to claim 3, wherein the first sensor and the second sensor are arranged non-overlapping.

10. A magnetic field sensor according to claim 3, wherein a magnetic field concentrator is arranged adjacent to the second sensor.

11. A magnetic field sensor according to claim 10, wherein the magnetic field concentrator redirects magnetic field components acting in the plane at least partially into a direction perpendicular to the plane.

12. A magnetic field sensor according to claim 7, wherein the second sensor protrudes beyond a circumference portion of the first sensor, so that the first sensor is operative as a magnetic field concentrator for the second sensor.

13. A magnetic field sensor according to claim 3 comprising a plurality of second sensors arranged offset to the center of the first sensor.

14. A magnetic field sensor according to claim 12, wherein the second sensors which are arranged offset are arranged symmetrically to the center of the first sensor.

15. A magnetic field sensor, comprising
a first sensor comprising an output for a first signal indicating a magnetic field acting in a plane; and
a second sensor comprising an output for a second signal indicating a component of the magnetic field perpendicular to the plane,
wherein the second sensor is arranged centrally with regard to the first sensor.

16. A magnetic field sensor, comprising
a first sensor comprising an output for a first signal indicating a magnetic field acting in a plane;
a second sensor comprising an output for a second signal indicating a component of the magnetic field perpendicular to the plane; and
a magnetic field concentrator arranged adjacent to the second sensor.

17. A magnetic field sensor, comprising
a first sensor comprising an output for a first signal indicating a magnetic field acting in a plane; and
a second sensor comprising an output for a second signal indicating a component of the magnetic field perpendicular to the plane,
wherein the first sensor and the second sensor are arranged non-overlapping.

18. An apparatus for detecting a magnetic field, comprising
a first detector for detecting a magnetic field acting in a plane; and
a second detector arranged with reference to the first detector to detect a component of the magnetic field perpendicular to the plane.

19. A sensor, comprising:
a magnetic field sensor comprising a first sensor with an output for a first signal indicating a magnetic field acting in a plane, and a second sensor with an output for a second signal indicating a component of the magnetic field perpendicular to the plane; and
a signal-processing circuit comprising a first input coupled to the output of the first sensor, a second input coupled to the output of the second sensor and comprising an output for an output signal indicating a magnetic field acting in the plane of the first sensor and corrected with reference to the magnetic field component acting perpendicular to the plane based on the signal applied to the second input.

20. A sensor, comprising:
a magnetic field sensor comprising a first sensor with an output for a first signal indicating a magnetic field acting in a plane, and a second sensor with an output for a second signal indicating a component of the magnetic field perpendicular to the plane; and
a signal-processing circuit comprising a first input coupled to the output of the first sensor, a second input coupled to the output of the second sensor and comprising an output for an output signal indicating, based on the signal applied to the second input, whether a magnetic field to be detected is present.

21. A sensor, comprising:
a magnetic field sensor comprising a first sensor with an output for a first signal indicating a magnetic field acting in a plane, and a second sensor with an output for a second signal indicating a component of the magnetic field perpendicular to the plane; and
a signal-processing circuit comprising a first input coupled to the output of the first sensor, a second input coupled to the output of the second sensor and comprising an output for a position signal, indicating, based on a position of the second sensor with regard to the first sensor and based on a signal applied to the second input, a position of the magnetic field sensor with regard to a magnet.

22. A sensor, comprising
a magnetic field sensor comprising a first sensor with an output for a first signal indicating a magnetic field acting in a plane, and a plurality of second sensors respectively comprising at least one output for a second signal indicating a component of the magnetic field perpendicular to the plane; and
a signal-processing circuit comprising a first input coupled to the output of the first sensor, a plurality of second inputs coupled to the outputs of the second sensors and comprising an output for an output signal indicating, based on a mean value of the signals applied to the second inputs, whether a magnetic field to be detected is present.

23. A sensor, comprising:
a magnetic field sensor comprising a first sensor with an output for a first signal indicating a magnetic field acting in a plane, and a plurality of second sensors respectively comprising at least one output for a second signal indicating a component of the magnetic field perpendicular to the plane;
a signal-processing circuit comprising a first input coupled to the output of the first sensor, a plurality of second inputs coupled to the outputs of the second sensors and comprising an output for an output signal indicating, based on the differences of the signals applied to the second inputs, an inclination of the magnetic field with regard to the magnetic field sensor.

24. A sensor according to claim 23, wherein the signal-processing circuit further outputs an error signal based on the differences of the signals applied to the two inputs or indicates an output signal of the first sensor corrected based on the detected differences with regard to the magnetic field component acting perpendicular to the plane.

25. A method for detecting a magnetic field in a plane, comprising the following steps:
detecting an output signal of a first sensor detecting the magnetic field acting in the plane;
detecting an output signal of a second sensor detecting a magnetic field component perpendicular to the plane; and
based on the output signal of the second sensor, correcting the output signal of the first sensor with regard to the magnetic field component acting perpendicular to the plane.

26. A method for determining whether a magnetic field is applied to a magnetic field sensor, wherein the magnetic field sensor includes a first sensor for detecting a magnetic field acting in a plane and a second sensor for detecting a component of the magnetic field acting perpendicular to the plane, comprising the following steps:
detecting a magnetic field component acting perpendicular to the plane; and
determining, based on a level of the magnetic field component detected perpendicular to the plane, whether the magnetic field is present.

27. A method according to claim 26, wherein the magnetic field sensor includes a plurality of second sensors, comprising the following steps:
detecting the output signals of the second sensors;
forming the mean value of the output signals; and
determining, based on the mean value, whether the magnetic field is present.

28. A method according to claim 26, wherein the magnetic field sensor includes a plurality of second sensors, comprising the following steps:
detecting the output signals of the second sensors;
determining differences of the output signals of the second sensors; and
determining, based on the differences, an inclination of the magnetic field with regard to the magnetic field sensor.

29. A method according to claim 28, comprising the following steps:
depending on an amount of the detected differences, generating an error signal; or
based on the detected differences, correcting an output signal of the first sensor.

30. A method according to claim 26, wherein the presence of the magnetic field is monitored during the operation of the magnetic field sensor.

31. A method for determining a position of a magnetic field sensor with reference to a magnetic field, wherein the magnetic field sensor includes a first sensor for detecting a magnetic field acting in a plane and a second sensor for detecting a component of the magnetic field acting perpendicular to the plane, comprising the following steps:
detecting the magnetic field component acting perpendicular to the plane;
based on a position of the second sensor with regard to the first sensor and on the level of the magnetic field component detected perpendicular to the plane, determining the position of the magnetic field sensor with regard to the magnetic field.

32. A method according to claim 31, wherein the second sensor is arranged centrally with regard to the first sensor, so that a minimum level of the magnetic field component detected perpendicular to the plane indicates an optimum position of the magnetic field sensor with regard to the magnetic field.

33. A method for manufacturing a magnetic field sensor, comprising the following steps:
providing a substrate;
generating a first sensor structure on the substrate such that the sensor structure detects a magnetic field component applied perpendicular to a surface of the substrate; and
generating a second sensor structure on the substrate, wherein the second sensor structure is operative to detect a magnetic field in parallel to the surface of the substrate.

34. A method according to claim 33, comprising the following steps:
generating a signal-processing circuit in the substrate.

35. A method according to claim 33, wherein the first sensor structure and the second sensor structure are generated by planar process steps.

36. A method according to claim 33, wherein the first sensor structure is generated in the substrate, and wherein the second sensor structure is generated on the substrate.

37. A method according to claim 33, wherein the first sensor structure and the second sensor structure are generated at least partially overlapping.

38. A method according to claim 37, wherein the second sensor structure is generated on the substrate such that the first sensor structure is arranged centrally with regard to the second sensor structure.

39. A method according to claim 33, wherein the first sensor structure and the second sensor structure are not generated overlapping, wherein the method further includes the following steps:
generating a magnetic field concentrator adjacent to the first sensor structure to redirect the magnetic field components acting parallel to the surface at least partially into a direction perpendicular to the surface of the substrate.

40. A method according to claim 39, wherein the magnetic field concentrator is generated on the surface of the substrate at least partially overlapping the first sensor structure.

41. A method according to claim 33, wherein the step of generating a first sensor structure on the substrate includes generating a plurality of first sensor structures.

42. A method according to claim 41, wherein the first sensor structures are arranged symmetrically to the center of the second sensor structure.

43. A method according to claim 33 for manufacturing a magnetic field sensor at the wafer level with a plurality of magnetoresistive devices.

44. A method according to claim 33, wherein the second sensor structure is a magnetoresistive sensor structure.

45. A method according to claim 44, wherein the magnetoresistive structure is an AMR structure, a GMR structure, a CMR structure, an EMR structure, a TMR structure or a magnetoresistive structure.

46. A method according to claim 33, wherein the first sensor structure is a Hall sensor structure.
